(19) United States
(12) Patent Application Publication
(10) Pub. No.: US 2013/0078424 A1
(43) Pub. Date: Mar. 28, 2013

(54) Hexagonal Boron Nitride Substrate With Monatomic Layer Step, And Preparation Method And Application Thereof

(71) Applicants: Guqiao Ding, Shanghai (CN); Shujie Tang, Shanghai (CN); Xiaoming Xie, Shanghai (CN); Mianheng Jiang, Shanghai (CN)

(72) Inventors: Guqiao Ding, Shanghai (CN); Shujie Tang, Shanghai (CN); Xiaoming Xie, Shanghai (CN); Mianheng Jiang, Shanghai (CN)

(21) Appl. No.: 13/580,267

(22) PCT Filed: Aug. 5, 2011
(86) PCT No.: PCT/CN2011/078061

§ 371 Date: Aug. 21, 2012

(30) Foreign Application Priority Data
Jul. 22, 2011 (CN) 201110206590.X

(51) Int. Cl. C23C 16/02

(52) U.S. Cl. CPC C23C 16/0254; B82Y 30/00
USPC 428/141; 427/255.28; 977/902

(57) ABSTRACT

The present invention provides a hexagonal boron nitride (hBN) substrate with a monatomic layer step and a preparation method thereof, where a surface of the hBN substrate is cleaved to obtain a fresh cleavage plane, and then hBN is etched by using hydrogen at a high temperature to obtain a controllable and regular monatomic layer step. The present invention utilizes an anisotropic etching effect of hydrogen on the hBN and controls an etching rate and degree of the etching by adjusting a hydrogen proportion, the annealing temperature, and the annealing time, so as to achieve the objective of etching the regular monatomic layer step. The preparation process is compatible with the process of preparing graphene through a chemical vapor deposition (CVD) method, and is applicable to preparation of a graphene nanoribbon. The present invention is mainly applied to new graphene electronic devices.

### BACKGROUND OF THE PRESENT INVENTION

1. Field of Invention

The present invention relates to a hexagonal boron nitride (hBN) substrate with a monatomic layer step and a method for etching a monatomic layer step on an insulated-substrate hBN, and belongs to the field of new materials and nano-materials.

2. Description of Related Arts

A substrate material for graphene is quite important. Currently, the graphene that grows on a metal substrate through a chemical vapor deposition (CVD) method needs to be transferred on an insulated substrate. For a currently frequently used SiO₂/Si substrate, due to the doping of graphene local charge carriers caused by surface charge gathering and a scattering effect incurred by phonons located on a SiO₂-graphene interface to the graphene charge carriers, an upper limit of an electron mobility of the graphene transferred onto the SiO₂/Si substrate is lowered to 40000 cm²/Vs, so that a performance of a graphene field effect transistor is greatly decreased. In 2008, Chen J. H. published a thesis, Intrinsic and Extrinsic Performance Limits of Graphene Devices on SiO₂, on Nature Nanotechnology, volume 3, 206, to research the limits of graphene devices on a SiO₂ substrate. The hBN is isoelectronic with the graphene, has the same stratified structure as the graphene, does not have any dangling bond on the (0001) face, and has the lattice mismatch regarding the graphene being only 1.7%. The thesis, Scanning Tunnelling Microscopy and Spectroscopy of Ultra-flat Graphene on Hexagonal Boron Nitride, written by Xue J. and published on Nature Materials in 2011 indicates that, the electron mobility of the graphene transferred on an ultra-flat hBN is two orders of magnitude higher than that of the graphene on the SiO₂, so that the hBN is recognized as the best graphene substrate at present.

Now, a number of scientific literatures report an implementation of mechanically transferring the graphene on the hBN substrate which is also stripped from a bulk hBN mechanically; and the experimental result shows that the electron mobility is increased by an order of magnitude compared with that on the SiO₂. However, the area of a sample obtained by the mechanical stripping and transferring method is limited, the number of the graphene layer is out of control and a success rate is low, so that the mechanical stripping and transferring method is only suitable for scientific researches. In 2011, we published the thesis, Direct growth of few layer graphene on hexagonal boron nitride by CVD, on Carbon to report a method for preparing the graphene by using the hBN as the substrate and through the CVD method and realized the direct growth of the graphene on the hBN. A surface microstructure of the hBN is quite important to the graphene no matter the graphene grows on the surface of the hBN by CVD or the graphene is transferred on the surface of the hBN by the mechanical stripping method. The implementation of a nanostructure, especially a nanostructure with the thickness of a single atomic layer, on the hBN substrate directly affects or even regulates graphene nucleation and growth.

However, pre-treatment of the hBN substrate is currently unavailable. No matter the graphene directly grow through the CVD method or the graphene is transferred onto the hBN, for the applied hBN substrate, only the superficial hBN is stripped off to uncover a fresh cleavage plane.

### SUMMARY OF THE PRESENT INVENTION

The present invention, according to unavailability of pre-treatment of an hBN substrate before transferring graphene or directly growing the graphene on the hBN substrate in the prior art, provides an hBN substrate with a monatomic layer step and a method for etching a regular monatomic layer step on an insulated-substrate hBN.

The present invention is implemented according to the following technical solution: cleaving the hBN substrate to obtain a fresh atomic surface; then, performing high-temperature annealing treatment in a specific atmosphere to obtain the hBN substrate with a regular monatomic layer step.

The present invention adopts the technical solution below.

An hBN substrate with a monatomic layer step, wherein a cleavage plane of the hBN substrate has a monatomic layer step and the height of a single step of the monatomic layer step is the thickness of a boron nitride (BN) atomic layer.

Preferably, the distance between the monatomic layer steps is 50 nm to 20 μm. The optimal step distance is 500 um to 5 μnm. The distance is the width of every step.

Preferably, the length of the monatomic layer steps is 100 nm to 100 μm.

The hBN substrate comprises, but is not limited to, bulk hBN monocrystalline, a monocrystal hBN sheet obtained by a mechanical stripping method and an hBN substrate prepared by a CVD method.

The cleavage plane of the hBN substrate is a fresh hBN atomic surface with less defects, which is uncovered by the mechanical stripping method through removing the hBN on the uppermost layer and simultaneously carrying off the defects, such as an adsorbed substance on the surface and a mechanical scratch on the surface.

The present invention further discloses a preparation method of an hBN substrate with a monatomic layer step, comprising the following steps: cleaving a surface of an hBN substrate to obtain a fresh atomic surface; then, performing high-temperature annealing treatment on the atomic surface in a gas mixture of hydrogen and argon, so as to obtain the hBN substrate with the monatomic layer step.

The hBN substrate cleavage is to uncover a fresh hBN atomic surface with less defects by a mechanical stripping method through removing the hBN on the uppermost layer and simultaneously carrying off the defects, such as an adsorbed substance on the surface and a mechanical scratch on the surface.

Preferably, in the gas mixture of the hydrogen and the argon, a volume ratio of the hydrogen to the argon is 1:1-1:10, and optimally 1:3-1:9.

Preferably, an annealing temperature of the high-temperature annealing treatment is 1000° C. to 1200° C., and annealing time thereof is 10 min to 300 min. The annealing temperature is able to regulate an etching rate, and the annealing time is able to regulate the distribution of monatomic layer steps.

A key problem solved by the present invention is how to prepare a step with the thickness of a monatomic layer on an hBN surface. After a large number of experiments, inventors of the present invention surprisedly find that, in a high temperature, the hydrogen has an anisotropic etching effect on the hBN. The etching occurs along the defects with dangling bonds on a cleavage plane of the hBN and occurs along an edge of the cleavage plane. Under an appropriate condition, the etching rate of the hydrogen on the edge of the hBN is far greater than that of the etching inside the surface of the hBN, and at the same time, through regulating the temperature and content of the hydrogen, the etching rate could be controlled, thereby achieving the effect of etching layer by layer from a topmost plane and eventually forming the monatomic step.

Moreover, the technology, provided by the present invention, of etching a nitrogen atomic layer step on the hBN substrate and a current technological progress of preparing graphene through a CVD method could be integrated into a CVD apparatus for implementation, that is, after realizing the step with the thickness of the monatomic layer on the hBN substrate, without taking out of a sample, the graphene CVD growth is directly performed, thereby avoiding polluting the surface of the sample. Through optimizing the technology of preparing the graphene by the CVD and controlling graphene nucleation on the edge of the step, a high-quality graphene nanoribbon could be achieved.

The present invention also discloses applications of the hBN substrate with the monatomic layer step, that is, the preparations of graphene nanoribbons and electronic devices based on the graphene nanoribbon.

Through the direct growth of the graphene on the hBN substrate with a monatomic layer step provided by the present invention, or through transferring the graphene onto the surface of the hBN by a mechanical stripping method, uniform monolayer graphene and double-layer graphene could always be achieved, and the graphene nanoribbon can be directly prepared on the hBN substrate, so that the graphene electronic device is provided with the foundation.

### BRIEF DESCRIPTION OF THE DRAWINGS

FIG. 1 is an atomic force microscopy image of hBN after mechanical stripping in Embodiment 1.

FIG. 2 is an atomic force microscopy image of hBN with a monatomic layer step after etching in Embodiment 1.

FIG. 3 is a surface atomic force microscopy image of hBN after etching in Embodiment 2.

FIG. 4 is a surface atomic force microscopy image of hBN after etching in Embodiment 3.

### DETAILED DESCRIPTION OF THE INVENTION

Substantive features and outstanding progresses of the present invention are further described with reference to the following specific embodiments, but the present invention is not limited to the embodiments.

### Embodiment 1

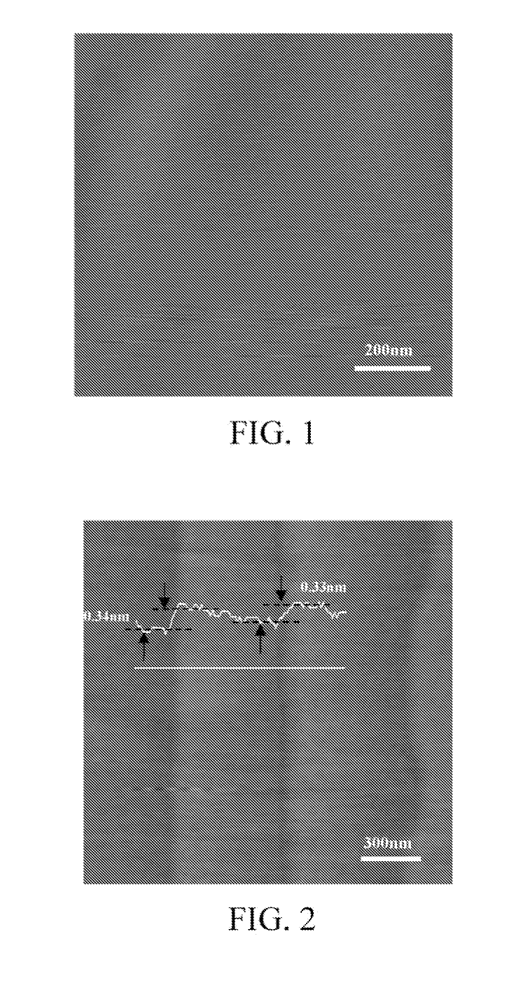

Step 1: Take a monocrystal hBN sheet as a raw material and obtain, through mechanical stripping on a SiO₂/Si substrate, an hBN lamella with a fresh cleavage plane, as is shown in FIG. 1, a surface thereof is quite smooth without any steps.

Step 2: Put an hBN/SiO₂ substrate obtained through Step 1 in a tube furnace, input a 300-sccm gas mixture of hydrogen and argon (H₂:Ar=1:3, volume ratio), heat up the temperature to 1200° C. at a rate of 20° C./min, and keep the temperature for 10 min followed by furnace cooling, so that a step as high as a monatomic layer and shown in FIG. 2 is obtained, where height analysis shows that a height difference of the step is 0.34 nm and 0.33 nm, which is a single BN atomic layer step, and a distance between the steps is about 500 nm.

### Embodiment 2

Step 1: Take a monocrystal hBN bulk as a substrate and remove an hBN surface layer by a mechanical stripping method.

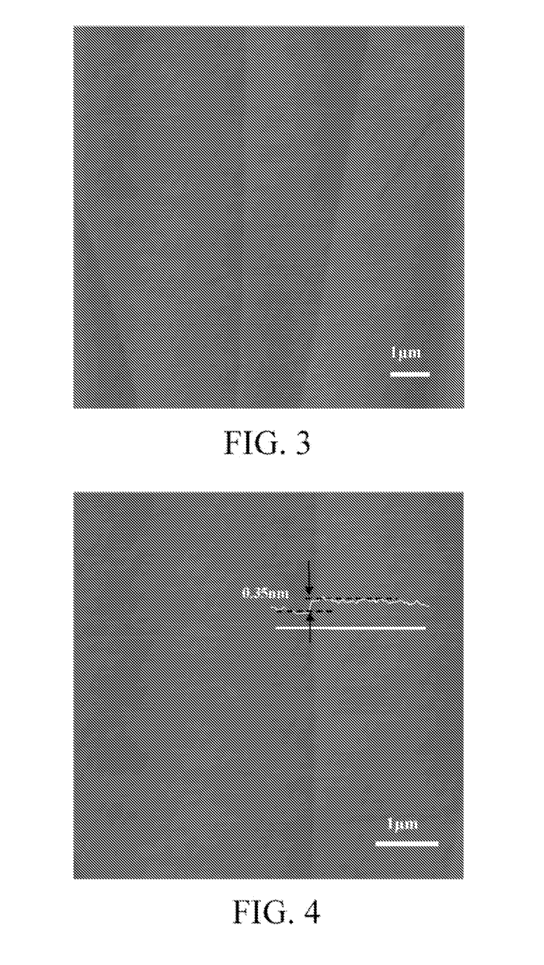

Step 2: Put the substrate in a tube furnace, input a 300-sccm gas mixture of hydrogen and argon (H₂:Ar=1:6, volume ratio), heat up the temperature to 1100° C. at a rate of 20° C./min, and keep the temperature for 50 min followed by furnace cooling, so that a step as high as a monatomic layer and shown in FIG. 3 is obtained. A distance between the steps is 1-5 μm.

### Embodiment 3

Step 1: Take hBN which grows through a CVD method as a substrate and remove an hBN surface layer through a mechanical stripping method. A process of preparing the hBN through the CVD method is as follows: borazine is used as a BN source, argon as a carrier gas, metal Ni as a substrate at 1000° C., an hBN film is obtained after growing for half an hour under a 5-Pa pressure and the hBN film transferred onto a SiO₂/Si substrate.

Step 2: Put the substrate in a tube furnace, input a 300-sccm gas mixture of hydrogen and argon (H₂:Ar=1:9, volume ratio), heat up the temperature to 1100° C. at a rate of 20° C./min, and keep the temperature for 300 min followed by furnace cooling, so that a step as high as a monatomic layer and shown in FIG. 4 is obtained. A height analysis result is 0.35 nm, which is a single BN atomic step, and a distance between the steps is 2-5 μm.

1. A hexagonal boron nitride (hBN) substrate with a monatomic layer step, wherein a cleavage plane of the hBN substrate has a monatomic layer step and the height of a single step of the monatomic layer step is the thickness of a boron nitride (BN) atomic layer.

2. The hBN substrate with a monatomic layer step as in claim 1, wherein a distance between the monatomic layer steps is 50 nm to 20 μm.

3. The hBN substrate with a monatomic layer step as in claim 1, wherein a distance between the monatomic layer steps is 500 nm to 25 μm.

4. The hBN substrate with a monatomic layer step as in claim 1, wherein the length of the monatomic layer step is 100 nm to 100 μm.

5. The hBN substrate with a monatomic layer step as in claim 1, wherein the hBN substrate is selected from bulk hBN monocrystalline, a monocrystal hBN sheet obtained through a mechanical stripping method and an hBN substrate prepared through a chemical vapor deposition (CVD) method.

6. A preparation method of the hexagonal boron nitride (hBN) substrate with a monatomic layer step as in claim 1, comprising the following steps: cleaving a surface of the hBN substrate to obtain a fresh atomic surface; performing annealing treatment on the atomic surface in a gas mixture of hydrogen and argon, so as to obtain the hBN substrate with the monatomic layer step.

7. The preparation method of the hBN substrate with a monatomic layer step as in claim 6, wherein in the gas mixture of the hydrogen and the argon, a volume ratio of the hydrogen to the argon is 1:1 to 1:10.

8. The preparation method of the hBN substrate with a monatomic layer step as in claim 6, wherein an annealing temperature of the annealing treatment is 1000° C. to 1200° C., and annealing time is 10 min to 300 min.

9. Applications of the hexagonal boron nitride (hBN) substrate with a monatomic layer step as in claim 1 in preparation of graphene nanoribbons and electronic devices based on the graphene nanoribbon.
